(19) United States
(12) Patent Application Publication
(10) Pub. No.: US 2007/0178389 A1
(43) Pub. Date: Aug. 2, 2007

(54) Universal photomask

(76) Inventor: Chue San Yoo, Hsin-Chu (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 11/344,630

(22) Filed: Feb. 1, 2006

(51) Int. Cl. G03F 9/00; G03F 1/00

(52) U.S. Cl. 430/5; 430/22

(57) ABSTRACT

A mask set for forming a semiconductor device includes a universal mask used multiple times in the fabrication process. The universal mask may include contact structures, interconnect structures or both. For each level of use, the universal mask includes some features that provide connection between superjacent and subjacent features and other features that do not provide contact to superjacent or subjacent device features. When used at another level, the other features that did not provide contact between features in the previous location, may advantageously provide contact between superjacent and subjacent structures at the new level. A method for forming a semiconductor device using the described mask set is also provided. The invention further provides a computer program product that provides encoded instructions for forming such a mask set and an apparatus for receiving the instructions and forming the mask set.

### FIELD OF THE INVENTION

The present invention relates, most generally, to semiconductor manufacturing and photomask sets used in semiconductor manufacturing. More particularly, the present invention relates to a photomask set with a universal mask, a method for forming the mask set and a method for forming a semiconductor device using the mask set.

### BACKGROUND

In today's continuously emerging semiconductor manufacturing industry, device cost and manufacturing throughput have been and continue to be salient considerations. Semiconductor devices are manufactured using a coordinated set of photomasks. A photomask is required at each device level. Photomasks must be manufactured to high precision and accuracy standards and therefore the cost of the set of photomasks represents a significant portion of the cost associated with manufacturing the semiconductor device. A complete customized photomask set is required for each particular semiconductor device. For a device having a given level of complexity, then, it would be advantageous to form the device using as few photomasks as possible to minimize costs and maximize throughput. The number of device levels has a direct correlation to device complexity, however, and, traditionally, a dedicated and customized photomask is required for each device level.

United States Patent Application Publication US 2005/0110146, entitled METHOD FOR COMBINING VIA PATTERNS INTO SINGLE MASK, filed Nov. 24, 2003 and commonly owned by the same Assignee, provides a via mask useable at multiple levels of a particular semiconductor device, wherein the vias each connect to a metal line, in particular, either a dummy metal line or functional metal line. The contents of the aforementioned US Publ. 2005/0110146 are hereby incorporated by reference, as if set forth in their entirety.

Another limiting factor and concern in semiconductor device manufacturing is the proximity effect which results in a mask feature being formed to different dimensions and shapes on the actual semiconductor device depending on how the feature is situated on the photomask, i.e., different sizes are produced by nested, as opposed to isolated photomask features. It would clearly be advantageous to provide a mask with a pattern density consistent throughout the mask and therefore minimizing the “nested versus isolated” feature dichotomy.

The present invention addresses the above concerns with a novel mask set, an apparatus for forming the mask set, and a method for forming a semiconductor device using the mask set.

### SUMMARY OF THE INVENTION

To address these and other needs, and in view of its purposes, the present invention provides a universal interconnect pattern mask usable at multiple levels in the fabrication of a semiconductor device.

In one embodiment, the invention provides a photomask set for producing a semiconductor device. The photomask set comprises a plurality of masks alignable with one another to produce the semiconductor device and includes a first mask with a first pattern, a second mask with a second pattern and alignable over the first pattern, and a third mask with a third pattern and alignable over the second pattern. The mask set further includes a universal mask having a universal pattern and alignable between the first and second masks and between the second and third masks such that first features of the universal pattern provide connection between features of the first and second patterns but not to any features of the third pattern in the semiconductor device. Second features of the universal pattern provide connection between features of the second pattern and third pattern but not to any features of the first pattern in the semiconductor device.

In another embodiment, the invention provides a method for forming a semiconductor device and the semiconductor device structure so formed. The method includes forming a first pattern, forming a second pattern aligned over the first pattern and forming a third pattern aligned over the second pattern. Each pattern is different from the other patterns. The method further provides forming a universal pattern between the first pattern and the second pattern and between the second pattern and the third pattern using a single universal mask. First features of the universal mask provide connection between features of the first and second patterns but not to any features of the third pattern. Second features of the interconnect pattern provide connection between features of the second and third patterns but not to any features of the first pattern.

The invention further provides an apparatus for manufacturing a photomask set. The apparatus comprises a photomask manufacturing tool capable of receiving software instructions and a computer program product that provides encoded or other instructions to the photomask manufacturing tool to form the photomask set described above.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIG. 1 is an exploded perspective view showing an exemplary photomask set of the invention including a multiply used exemplary universal photomask;

FIG. 2 is an exploded perspective view showing another exemplary photomask set of the invention including a further multiply used exemplary universal photomask; and

FIG. 3 is an exploded perspective view showing yet another exemplary photomask set of the invention including a further multiply used exemplary universal contact/hole photomask

### DETAILED DESCRIPTION

The invention provides a mask set, also referred to as a photomask set, formed of conventional materials and used to produce a particular semiconductor device. In an exemplary embodiment, the masks are formed using quartz or another transparent material as the substrate and the opaque patterns formed on the mask are formed of chrome or other suitable opaque materials.

The invention may be used in conjunction with a mask set used in a positive photoresist system, in which the opaque pattern is transferred to a photoresist pattern on the substrate, or with a negative photoresist system, in which the inverse of the opaque pattern is transferred to a photoresist pattern on the substrate as will be transferred to the device. For example, in a positive photoresist system, the interconnect chrome pattern formed on an interconnect level mask is the same as the pattern formed in a photosensitive material on the device and therefore the pattern of the conductive or semiconductive material formed in the interconnect layer on the device after etching, in non-damascene technology. For contact masks using a positive photoresist lithography system, the contact hole formed in an interlevel dielectric material is formed from a transparent hole formed in and surrounded by an opaque area of the mask. In a positive photoresist system using damascene technology, the interconnect chrome pattern formed on an interconnect level mask will be the inverse of the pattern of conductive or semiconductive material ultimately formed in trenches or grooves formed in a dielectric layer. As such, in a positive photolithography system, the interconnect masks may include chrome areas that form the pattern area whereas the void, transmissive areas may form the interconnect pattern areas in damascene technology. An interconnect pattern is a pattern of interconnect leads—lines of conductive material that electrically connect laterally separated features and may be referred to as wires. Contacts and contact masks refer to contacts between device features at different device levels and vias, in particular, provide contact between a subjacent and superjacent metal layer. Throughout the specification, contacts and vias will be referred to collectively as contacts.

The photomask set is used to form a semiconductor device over a substrate that may include substructure device features. The invention provides various, customized photomask sets, each used to form a particular semiconductor integrated circuit device and including a universal mask used multiple times in the formation of the semiconductor device. The interconnect layers are patterned using conventional photolithography techniques in conjunction with conventional damascene techniques or conventional etching techniques in which the interconnect material is patterned and etched. For each mask level, the mask pattern is transferred to a corresponding device layer.

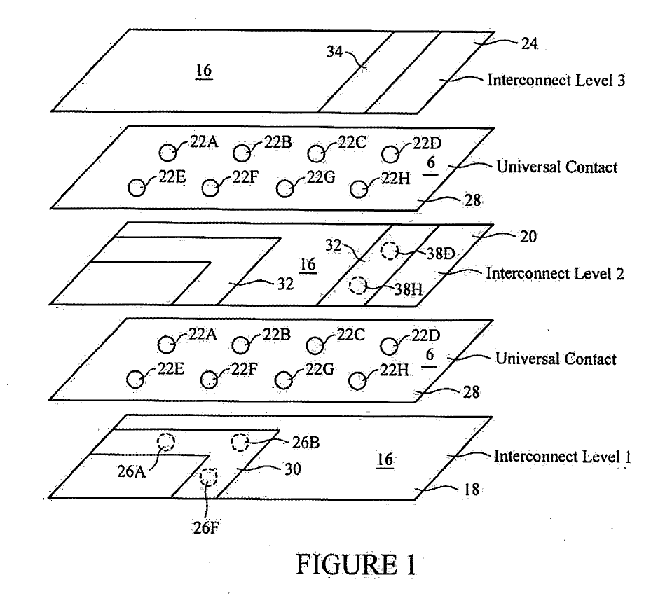

FIG. 1 is an exploded view showing an exemplary universal mask of the invention. Single universal mask 28 is a contact hole mask that is used to provide contact between interconnect level 1 and interconnect level 2 as well as to provide contact between interconnect level 2 and interconnect level 3. It should be understood that this is exemplary only and in other embodiments, the single universal mask may be used to provide contact between additional layers or it may include interconnect features or both interconnect features and contact features as will be shown in other exemplary embodiments. FIG. 1 is an exploded view showing interconnect layer 3 positioned over interconnect level 2 which is, in turn, positioned over interconnect level 1. The masks are generally aligned over one another in the illustration of FIG. 1. It should be understood that, in use, the respective masks form patterns in successive device layers, that are aligned over and with respect to, one another.

The aligned masks of FIG. 1 include interconnect level 1 mask 18, interconnect level 2 mask 20 and interconnect level 3 mask 24, as well as universal mask 28. Universal mask 28 includes openings or contact holes 22A-22H which are intended to be exemplary only. Contact holes 22A-22H may be transmissive holes formed in opaque section 6 or the polarity may be reversed. The area of the contact holes may be substantially greater than 10% of the area of the universal mask, in various exemplary embodiments. It should be further understood that the illustrated portions each of the masks includes a pattern that represents only a small portion of the overall pattern for that device layer. Interconnect level 1 mask 18 includes first portion 30 of the interconnect level 1 pattern. Interconnect level 2 mask 20 includes second portion 32 of the interconnect level 2 pattern. It can be seen that second portion 32 is aligned over first portion 30 and that contact holes 22A, 22B and 22F are aligned over first portion 30 as indicated by the dashed lines of contact locations 26A, 26B and 26F. Contact holes 22A, 22B and 22F are aligned between first portion 30 and second portion 32 and will provide contact between those levels when the mask set is used to form a semiconductor device. Contact holes 22A, 22B and 22F therefore form a group of contact holes that provide contact between the first and second interconnect levels but not between the second and third interconnect levels. Similarly, contact holes 22D and 22H are aligned over third portion 32 of the interconnect level 2 pattern of mask 20 and between third portion 32 and fourth portion 34 of the interconnect level 3 pattern of mask 24 but not between the first and second interconnect levels, when the masks are aligned over one another. When features are “aligned over” one another, it is meant that they overlie each other when the masks of the mask set are aligned over one another. The dashed patterns of contact locations 38D and 38H are indicative of the contact locations provided by contact holes 22D and 22H, respectively. If additional interconnect levels are used, the same universal mask 28 will be used to provide contact between interconnect level 3 and one or more superjacent layers. Various combinations of contact holes 22A-22H, including contact holes utilized at previous levels and contact holes not previously used, may be used to provide contact between the subsequent levels.

The method to form a semiconductor device using the illustrated mask set includes forming a first interconnect pattern defined by a first interconnect mask and formed of a conductive or semiconductive material over a substrate that may include substructure devices, forming a dielectric layer over the first interconnect pattern and using the universal mask 28 to provide contact to features of the first interconnect pattern using a selected group of contact holes. A second interconnect pattern may be formed over the first dielectric layer using the same or different techniques as used for forming interconnect level 1 and the conductive interconnect pattern is routed appropriately to utilize the contacts formed to the first interconnect level. A second dielectric layer may be formed over the second interconnect pattern and universal mask 28 used to form contact through the second dielectric and to desired portions of the second interconnect pattern. A third interconnect pattern may then be formed and routed to utilize contacts to the second interconnect pattern. Conventional etching and/or damascene patterning technologies may be used to form patterns in the respective layers. Unlike the exemplary embodiment shown in FIG. 1, one or more common contact holes may be used to provide contact between more than one set of adjacent interconnect patterns. Further interconnect patterns may subsequently be formed, using various groups of the contact holes of universal mask 28 and provide connection between the interconnect patterns of subsequent levels e.g. contact holes 22A, 22B and 22F may provide connection between features of fourth and fifth interconnect levels (not shown). The semiconductor device is designed such that some of the contacts of universal mask 28, at each level, will extend through one dielectric material and simply terminate at a lower lever such as dielectric, where no electrical connection is made, i.e., the invention is not limited to each contact extending down to provide contact to a subjacent functional or dummy feature.

The mask set may be generated using a conventional photomask manufacturing apparatus and using conventional methods. A computer system can run software employing computer-aided design (CAD) methods. The photomask manufacturing tool is capable of receiving software instructions and the invention provides software, i.e., a computer program product, that provides encoded or other instructions to the photomask manufacturing tool including instructions to form a single contact mask having a plurality of contact structure and multiple interconnect masks in one embodiment such as illustrated in FIG. 1. Adjacent interconnect masks include patterns that are routed to utilize selected groups of contact hole structures formed in the universal contact hole mask which is used at all contact and via levels. The mask set is designed and software provided to utilize various groups of contact holes to provide active connection between portions of one interconnect level that overlie a portion of a subjacent interconnect level, as previously described.

In another embodiment, the photomask manufacturing tool receives software instructions on how to form a universal mask having a plurality of features including interconnect structures and optionally additionally including contact structures, as well as multiple interconnect and/or contact masks. Adjacent ones of the other masks of the mask set include patterns that are routed to utilize interconnect features and/or contact hole structures formed in the universal mask which is multiply used. The mask set is designed and software provided to utilize various features of the universal mask to provide active connection between portions of superjacent and subjacent patterns, i.e. the features overlie each other.

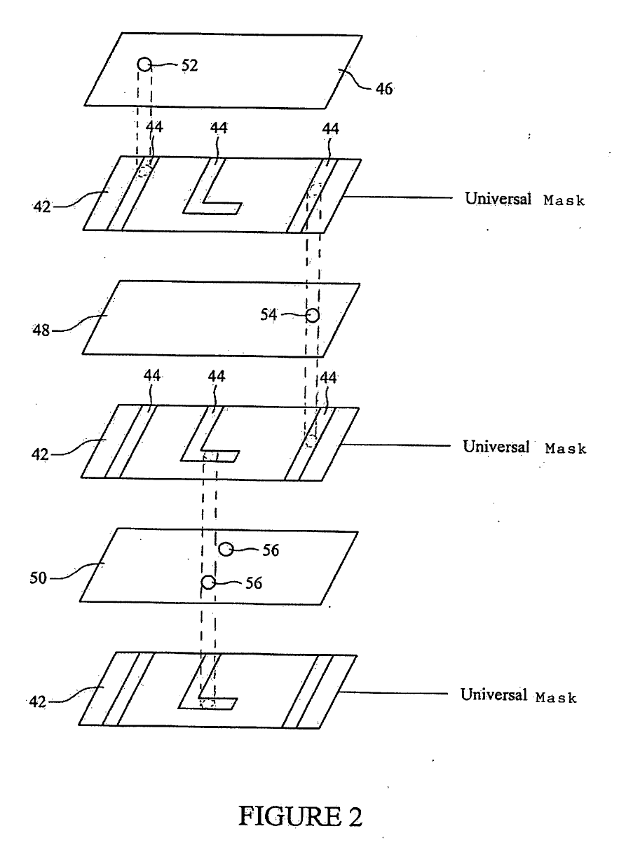

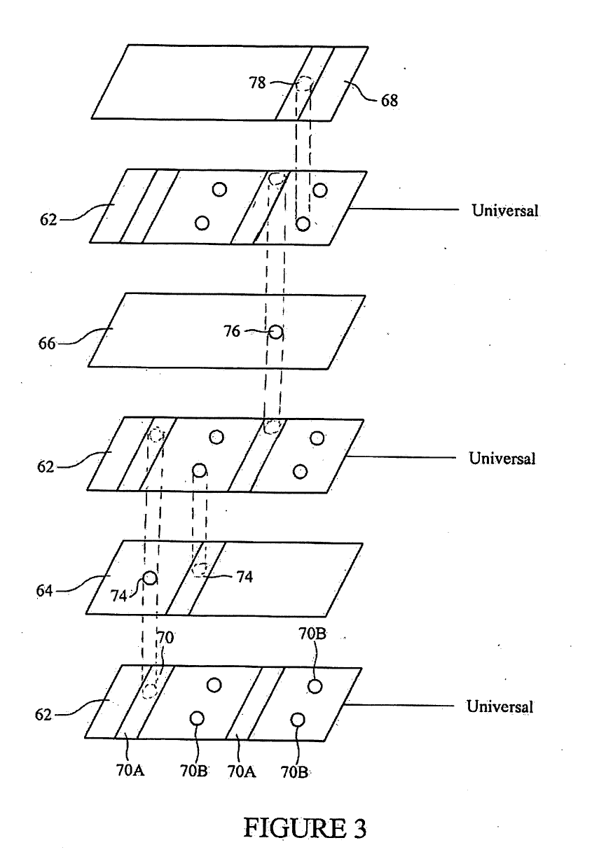

Each of FIGS. 2 and 3 is an exploded view showing an exemplary universal mask being used multiple times within a mask set. In each exemplary illustrated embodiment, there is the multiply used universal mask and three further different masks. In each case there is a first mask with a first pattern, a second mask with a second pattern aligned over the first pattern and a third mask with a third pattern aligned over the second pattern. In each case, the illustrated mask portions represent a small portion of a pattern used at a particular level of a semiconductor device. Each mask set is used to form a semiconductor device by successively using the masks to form patterns in successive layers formed on the semiconductor device. In each case, the universal mask has a universal pattern that is alignable between, for example, a first and second mask and also alignable between a second and third mask such that first features of the universal pattern, which may be a contact, an interconnect lead, or both, provide connection between features of the first and second patterns but do not provide connection to and are not aligned with, any features of the third pattern. Second features of the universal pattern which may be interconnect leads, contacts or both, provide connection between features of the second pattern and the third pattern but do not provide connection to nor are they aligned with, any features of the first pattern.

Referring to FIG. 2, universal mask 42 is an interconnect mask and includes interconnect pattern 44. The interconnect pattern 44 comprises interconnect lines and/or interconnect islands. The interconnect pattern area may be substantially greater than about 10% of the universal mask area, in various exemplary embodiments. Adjacent, i.e. directly superjacent and directly subjacent, contact masks include patterns that are routed to utilize selected groups of interconnect pattern structures formed in the universal mask which may be used at multiple interconnect levels and may be used at all interconnect levels, in one embodiment. The various features of interconnect pattern 44 are contacted by and provide contact to, contacts of the various masks: first mask 50 including contacts 56, second mask 48, including contact 54 and third mask 46, including contact 52. The dashed lines indicate contact being made through a dielectric layer at a particular level. Alternatively, the dashed lines indicate features that overlie one another when the mask set is aligned. The exemplary six masks shown in FIG. 2 represent part of a larger mask set used collectively to form a semiconductor device. As such, masks representing various other patterns may be used in conjunction with the illustrated mask set and may be used both prior to (below) or subsequent to (above) the illustrated mask set. Universal mask 42 may be used additionally, for example, over third mask 46, and/ or under first mask 50.

The exploded view illustration of FIG. 3 provides another exemplary embodiment of a universal mask of the invention. Universal mask 62 includes both contact structures and interconnect structures. The interconnect structure comprises interconnect lines and/or interconnect islands. For example, universal pattern 70 is formed of universal interconnect lines 70A and universal contacts 70B. The area of the interconnect lines and contact structures may be substantially greater than about 10% of the area of the universal mask, in various exemplary embodiments. Adjacent interconnect and contact masks include patterns that are routed to utilize selected groups of interconnect pattern and contact structures formed in the universal mask, which may be used at multiple interconnect and contact levels. Universal mask 62 may be used below first mask 64 and between first mask 64 and second mask 66 as well as in between second mask 66 and third mask 68. First mask 64 includes pattern 74 which includes an interconnect lead and a contact. Second mask 66 includes pattern 76 which is a contact structure in the illustrated embodiment. Third mask 68 includes pattern 78 which is an interconnect pattern in the illustrated embodiment. It should be understood that the contact pattern, interconnect pattern and combined contact/interconnect pattern may appear at different levels and may be used in various combinations and that universal mask 62 may be used multiple times in between and above or below these masks. Universal pattern 70 may result in structures being formed to extend through a subjacent layer such as a dielectric layer, that are “dead” structures, i.e., they do not provide contact to a subjacent layer. In other words, they do not necessarily connect to a functional or dummy subjacent feature.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A universal interconnect pattern mask usable at multiple levels in the fabrication of a semiconductor device and comprising an interconnect pattern.

2. The universal interconnect pattern mask as in claim 1, wherein said mask further comprises contact structures.

3. The universal interconnect pattern mask as in claim 2, wherein an area of said interconnect pattern and said contact structures comprises greater than about 10% of an area of said universal interconnect pattern mask.

4. A photomask set for producing a semiconductor device comprising:
a plurality of masks alignable with one another to produce said semiconductor device and comprising:
a first mask with a first pattern;
a second mask with a second pattern and alignable over said first pattern;
a third mask with a third pattern and alignable over said second pattern; and
a universal mask having a universal pattern alignable between said first and second masks and between said second and third masks such that first features of said universal pattern provide connection between features of said first and second patterns but not to any features of said third pattern in said semiconductor device, and second features of said universal pattern provide connection between features of said second pattern and said third pattern but not to any features of said first pattern in said semiconductor device.

5. The photomask set as in claim 4, wherein said universal pattern comprises an interconnect pattern.

6. The photomask set as in claim 5, wherein said universal pattern further includes contact structures.

7. The photomask set as in claim 4, wherein said photomask set is formed by a manufacturing method that utilizes software.

8. The photomask set as in claim 7, wherein said manufacturing method includes computer-aided design (CAD).

9. The photomask set as in claim 7, wherein said manufacturing method includes a computer system that runs said software.

10. The photomask set as in claim 6, wherein an area of said universal pattern comprises greater than about 10% of an area of said universal mask.

11. The photomask set as in claim 4, further comprising a fourth mask with a fourth pattern alignable over said third mask with said universal mask alignable therebetween, wherein further features of said interconnect pattern provide connection between features of said fourth pattern and said third pattern but not to any features of said second pattern.

12. The photomask set as in claim 4, wherein
said first features overlie features of said first pattern and features of said second pattern overlie said first features when said masks are aligned over one another, and
said second features overlie further features of said second pattern and features of said third pattern overlie said second features when said masks are aligned over one another.

13. A structure of a semiconductor device comprising:
a first pattern,
a second pattern aligned over said first pattern,
a third pattern aligned over said second pattern, each of said first, second and third patterns being different from each other of said first, second and third patterns and being formed in a layer of said semiconductor device; and
a universal pattern disposed between said first pattern and said second pattern and between said second pattern and said third pattern, wherein first features of said universal pattern provide connection between features of said first and second patterns but not to any features of said third pattern in said semiconductor device, and second features of said universal pattern provide connection between features of said second pattern and said third pattern but not to any features of said first pattern in said semiconductor device.

14. The structure as in claim 13, wherein each of said first pattern, said second pattern, said third pattern and said universal pattern comprise conductive features.

15. The method as in claim 13, wherein said first pattern, said second pattern, said third pattern and said universal pattern are formed by etching into a respective dielectric material layer of said semiconductor device.

16. The structure as in claim 13, wherein said universal pattern is formed from a universal mask and an area of said universal pattern comprises greater than about 10% of an area of said universal mask.

17. The structure as in claim 13, wherein said universal pattern includes an interconnect pattern and each of said first, second and third patterns include at least contact structures.

18. The structure as in claim 17, wherein said universal pattern further includes contact structures and at least one of said first, second and third patterns further includes a pattern of interconnect leads as part thereof.

19. The structure as in claim 17, wherein said interconnect pattern comprises interconnect lines.

20. The structure as in claim 17, wherein said interconnect pattern comprises interconnect islands.
